(19) United States
(12) Patent Application Publication
(10) Pub. No.: US 2004/0017693 A1
(43) Pub. Date: Jan. 29, 2004

(54) Method for programming, reading, and erasing a non-volatile memory with multi-level output currents

(76) Inventors: Tung-Cheng Kuo, I-Lan Hsien (TW); Chien-Hung Liu, Taipei City (TW); Shyi-Shuh Pan, Kao-Hsiung City (TW); Shou-Wei Huang, Chi-Lung City (TW)

Correspondence Address: NAIPO (NORTH AMERICA INTERNATIONAL PATENT OFFICE), P.O. BOX 506, MERRIFIELD, VA, 22116, US

(21) Appl. No.: 10/064,518

(22) Filed: Jul. 23, 2002

(51) Int. Cl. G11C 16/04

(52) U.S. Cl. 365/185.03

(57) ABSTRACT

A non-volatile memory with multi-level output currents includes a plurality of memory cells. Each of the memory cells includes a non-conducting dielectric layer sandwiched between two isolation layers. The non-conducting dielectric layer includes a first region and a second region. By injecting electrons into the first region or the second regions, memory cells with different threshold voltages can be obtained. When reading the memory cells, multi-level output currents can be detected and thus, the non-volatile memory with multi-level output currents is obtained.

### BACKGROUND OF THE INVENTION

1. Field of the Invention

The present invention relates to a non-volatile memory. In particular, the present invention discloses a method for programming, reading, and erasing a non-volatile memory with multi-level output currents.

2. Background of the Invention

A read only memory (ROM) device, comprising a plurality of memory cells, is a type of semiconductor wafer device that functions as a data storage device. The ROM device is widely applied in computer data storage and memory. Depending on the method of storing data, the ROM can be classified as several types such as a mask ROM, programmable ROM (PROM), erasable programmable ROM (EPROM), electrically erasable programmable ROM (EEPROM) and a flash memory.

Differing from other types of ROMs which use either a polysilicon or metal floating gate, a nitride read only memory (NROM) uses an insulating dielectric layer as a charge-trapping medium. Due to the highly compact nature of the silicon nitride layer, hot electrons tunneling from the MOS transistor into the silicon nitride layer are trapped within to form an unequal concentration distribution which increases data reading speed and avoids current leakage.

A prior method of programming, reading and erasing an EEPROM cell capable of storing two binary bits of information is disclosed in U.S. Pat. No. 6,011,725. As per U.S. Pat. No. 6,011,725, a memory cell comprises a source, a drain, a channel positioned between the source and the drain, a non-conducting dielectric layer positioned on the channel and sandwiched between two isolation layers, and a conductor positioned on the isolation layer. The memory cell is able to store two binary bits by injecting electrons into a first region of the non-conducting dielectric layer close to the source and injecting electrons into a second region of the non-conducting dielectric layer close to the drain. However, two processes have to be completed in order to read the binary bits stored in the memory cell. That is, when reading one of the binary bits close to the source, a reading voltage is applied between the conductor and drain, grounding the source. When reading the other binary bits close to the drain, a reading voltage is applied between the conductor and the source, thus grounding the drain. In U.S. Pat. No. 6,011,725, these two processes have to be completed to read the binary bits stored in the memory cell, which substantially reduces the access rate of the memory.

### SUMMARY OF INVENTION

It is therefore a primary objective of the present invention to provide a method for programming, reading, and erasing a non-volatile memory with multi-level output current so as to improve the access rate of the memory.

In a preferred embodiment, a method for programming, reading, and erasing a non-volatile memory with multi-level output currents is provided. The non-volatile memory comprises a memory cell which comprises a source, a drain, a channel formed between the source and the drain, a first isolation layer formed on the channel, a non-conducting dielectric layer formed on the first isolation layer, a second isolation layer formed on the non-conducting dielectric layer and a conductor formed on the second isolation layer. The non-conducting dielectric layer comprises a first region nearby the drain and a second region nearby the source. Firstly, a programming step is performed to transform the memory cell into a predetermined state. The predetermined state comprises state(a)-both the first region and the second region are not injected with electrons, state(b)- the second region is not injected with electrons but the first region, state(c)—the first region is not injected with electrons but the second region, and state(d)—both the first region and the second region are injected with electrons. Then, a reading step is performed to obtain a predetermined output current from the memory cell. The predetermined output current comprises a maximum output current corresponding to the memory cell in the state (a), a first output current corresponding to the memory cell in the state (b), a second output current corresponding to the memory cell in the state (c), and a third output current corresponding to the memory cell in the state (d). A first erasing step is performed to remove electrons from the first region, and a second erasing step is performed to remove electrons from the second region.

It is an advantage of the present invention that only a single process is required to read the binary bits stored in the memory cell. As a result, the present invention can improve access rate, reduce power dissipation and increase capacity per unit area of a memory cell.

These and other objectives and advantages of the present invention will no doubt become obvious to those of ordinary skill in the art after having read the following detailed description of the preferred embodiment that is illustrated in the various figures and drawings.

### BRIEF DESCRIPTION OF DRAWINGS

FIG. 1 is a schematic diagram of an NROM memory cell according to the present invention;

FIG. 2 is a schematic diagram for illustrating injecting electrons into the first region 22a of the memory cell 10;

FIG. 3 is a schematic diagram for illustrating injecting electrons into the second region 22b of the memory cell 10; and

FIG. 4 is a schematic diagram for illustrating reading the memory cell 10.

### DETAILED DESCRIPTION

NROM is an example in the following preferred embodiment of the present invention. A method for fabricating NROM is disclosed in U.S. Pat. No. 5,966,603.

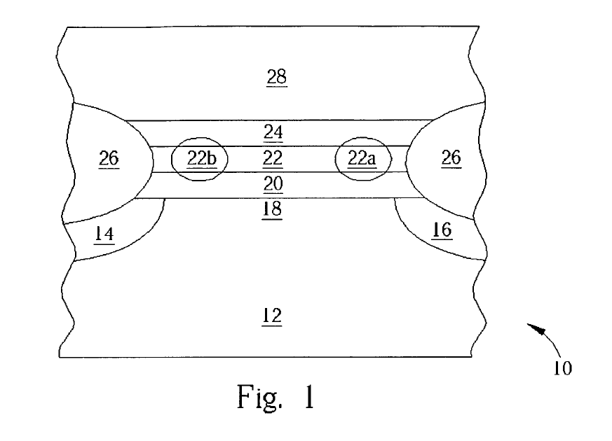

Please refer to FIG. 1. FIG. 1 is a schematic diagram of an NROM memory cell according to the present invention. As shown in FIG. 1, a memory cell 10 comprises a substrate 12, a source 14, a drain 16, and a channel 18 located between the source 14 and the drain 16. Above the channel 18 is a stacked structure composed of a first isolation layer 20, a non-conducting dielectric layer 22, and a second isolation layer 24. A field oxide layer 26 is formed on the source 14 and the drain 16. A conductor 28 is located on the second isolation layer 24 and the field oxide layer 26. Furthermore, the non-conducting dielectric layer 22 comprises a first region 22a close to the drain 16 and a second region 22b close to the source 14.

As disclosed in U.S. Pat. No. 6,011,725, storing electrons in the non-conducting dielectric layer 22 increases a threshold voltage of the memory cell 10. Furthermore, the threshold voltage of the memory cell 10 with electrons stored in the second region 22b is higher than that of the memory cell 10 with electrons stored in the first region 22a. Thus, by injecting electrons into the first region 22a or the second region 22b, memory cells having different threshold voltages are obtained. As reading the memory cells with different threshold voltages, multi-level output currents are detected. A non-volatile memory with multi-level output currents can be therefore obtained.

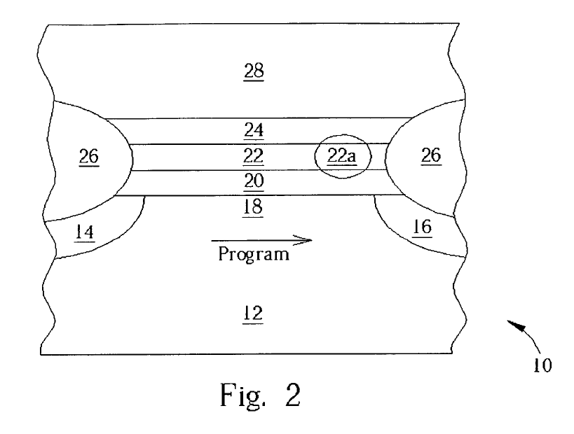

Please refer to FIG. 2. FIG. 2 is a schematic diagram for illustrating injecting electrons into the first region 22a of the memory cell 10. As shown in FIG. 2, a programming voltage of 10 volts is applied to the conductor 28, a programming voltage of 9 volts is applied to the drain 16, and the source 14 is grounded. As a result, a vertical electrical field perpendicular to the channel 18 and a lateral electrical field parallel to the channel 18 are created. The vertical and the lateral electrical field accelerate electrons from the source 14 to the drain 16. As electrons gain sufficient energy, they bypass isolation layer 20 and are trapped into region 22a of the non-conducting dielectric layer 22.

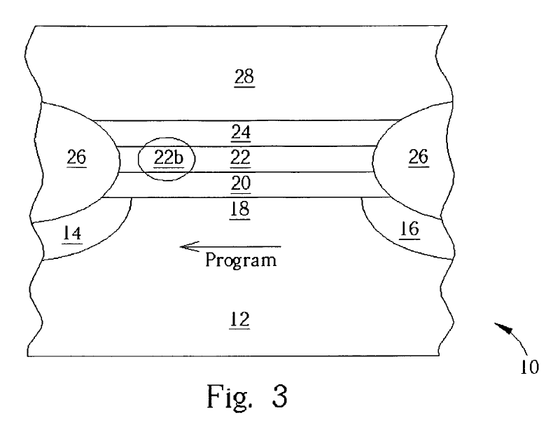

Please refer to FIG. 3. FIG. 3 is a schematic diagram for illustrating injecting electrons into the second region 22b of the memory cell 10. As shown in FIG. 3, a programming voltage of 10 volts is applied to the conductor 28, a programming voltage of 9 volts is applied to the source 14, and the drain 16 is grounded. As a result, a vertical electrical field perpendicular to the channel 18 and a lateral electrical field parallel to the channel 18 are created. The vertical and the lateral electrical field accelerate electrons from the drain 16 to the source 14. As electrons gain sufficient energy, they bypass the first isolation layer 20 and are subsequently trapped into region 22b of the non-conducting dielectric layer 22.

As a result, by injecting electrons into the first region 22a or the second region 22b, memory cell 10 has at least four predetermined states. They are state (a)—both the first region 22a and the second region 22b are not injected with electrons; state (b)—the second region 22b is not injected with electrons but the first region 22a; state (c)—the first region 22a is not injected with electrons but the second region 22b; and state (d)—both the first region 22a and the second region 22b are injected with electrons.

As described above, a threshold voltage of the memory cells 10 in state (d) is higher than that of the memory cells 10 in state (c). A threshold voltage of the memory cells 10 in state (c) is higher than that of the memory cells 10 in state (b). Similarly, a threshold voltage of the memory cells 10 in state (b) is higher than that of the memory cells 10 in state (a).

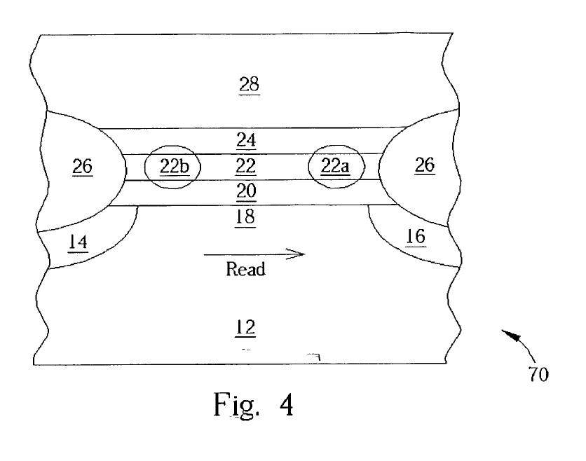

Please refer to FIG. 4. FIG. 4 is a schematic diagram for illustrating reading the memory cell 10. As shown in FIG. 4, a first reading voltage (such as 3 volts) is applied on the conductor 28, and a second reading voltage (such as 2 volts) is applied on the drain 16, and the source 14 is grounded. Accordingly, as reading the memory cell 10, a predetermined output current is obtained. The predetermined output current comprises a maximum output current corresponding to the memory cell 10 in the state (a), a first output current corresponding to the memory cell 10 in the state (b), a second output current corresponding to the memory cell 10 in the state (c), and a third output current corresponding to the memory cell 10 in the state (d). Furthermore, the maximum output current is larger than the first output current, which is larger than the second output current, which, in turn, is larger than the third output current.

Please refer to Table 1. Table 1 shows a relationship between electron injection positions and corresponding output currents of the memory cells according to the present invention. Wherein Id-HH is the maximum output current, Id-HL is the first output current, Id-LH is the second output current and Id-LL is the third output current. “Program-A” refers to an injection of electrons into the first region 22a close to the drain 16 and “Program-B” refers to an injection of electrons into the second region 22b close to the source 14. In the preferred embodiment of the present invention, quantities of electrons injected into the non-conducting dielectric layer 22 are adjusted so as to obtain four specific kinds of the output currents. That is, the first output current is approximately 75% of the maximum output current. The second output current is approximately 50% of the maximum output current. The third output current is approximately 25% of the maximum output current. As a result, the binary values, such as 11, 10,01 and 00, stored in the memory cells can be read by detecting the four specific kinds of output currents.

TABLE 1

| State | Output current | Program-A | Program-B |
|---|---|---|---|
| (a) | Id-HH | No | No |
| (b) | Id-HL | Yes | No |
| (c) | Id-LH | No | Yes |
| (d) | Id-LL | Yes | Yes |

The above-mentioned substrate 12 is composed of P-type silicon. The source 14 and the drain 16 are N-type. The first isolation layer 20 and the second isolation layer 24 are composed of silicon dioxide. The non-conducting dielectric layer 22 is composed of silicon nitride. The field oxide layer 26 is formed by thermal oxidation. The conductor 28 is composed of doped polysilicon.

In addition, the memory cells in the present invention can be electrically erased to be re-programmed. A first erasing step is performed to remove electrons from the first region 22a and a second erasing step is performed to remove electrons from the second region 22b. Therein the first erasing step comprises applying a first erasing voltage on the conductor 28 of the memory cell 10, and applying a second erasing voltage on the drain 16 of the memory cell 10. The first and the second erasing voltages are sufficient to cause electrons to be removed from the first region 22a. In addition, the second erasing step comprises applying a third erasing voltage on the conductor 28 of the memory cell 10, and applying a fourth erasing voltage on the source 14 of the memory cell 10. The third and the fourth erasing voltages are sufficient to cause electrons to be removed from the second region 22b.

In brief, the non-volatile memory in the present invention comprises a plurality of memory cells. Each memory cell comprises a non-conducting dielectric layer sandwiched between two isolation layers, and the non-conducting dielectric layer further comprises a first region and a second region. By injecting electrons into the first or second regions, memory cells with different threshold voltages can be obtained. When reading the above-mentioned memory cells, multi-level output currents can be obtained. As a result, a non-volatile memory with multi-level output currents is obtained.

Compared to the prior art, as reading a left bit and a right bit of a memory cell according the claimed invention, voltages are applied on the conductor, the drain, and the source, and then currents between the drain and the source are detected. During reading the left bit and the right bit of the memory cell, the source and the drain are not exchanged. Thus, only one process is required to read the binary bits stored in the memory cell. However, in the prior art, it needs to exchange the source and the drain during reading the left bit and the right bit of the memory cell. That is, it requires two processes to read the binary bits stored in the memory cell in the prior art. As a result, the present invention can improve an accessing rate, reduce power dissipation and increase capacity per unit area of a memory cell. In addition, the present invention can also be applied in the field of flash memory.

The above disclosure is based on the preferred embodiment of the present invention. Those skilled in the art will readily observe that numerous modifications and alterations of the device may be made while retaining the teachings of the invention. Accordingly, the above disclosure should be construed as limited only by the metes and bounds of the appended claims.

1. A method for reading a non-volatile memory with multi-level output currents, the non-volatile memory comprising a plurality of multi-level memory cells having at least a first, a second, a third, and a fourth programming states, the method comprising:
applying a first reading voltage on a conductor of the memory cell;
applying a second reading voltage on a drain of the memory cell; and
grounding a source of the memory cell, thereby obtaining an output current;
wherein the output current comprises a maximum output current corresponding to the memory cell in the first programming state, a first output current corresponding to the memory cell in the second programming state, a second output current corresponding to the memory cell in the third programming state, and a third output current corresponding to the memory cell in the fourth programming state.

2. The method of claim 1 wherein the maximum output current is larger than the first output current, which is larger than the second output current, which is larger than the third output current.

3. The method of claim 1 wherein each memory cell comprises a source, a drain, a channel formed between the source and the drain, a first isolation layer formed on the channel, a non-conducting dielectric layer formed on the first isolation layer, a second isolation layer formed on the non-conducting dielectric layer and a conductor formed on the second isolation layer, the non-conducting dielectric layer comprising a first region nearby the drain and a second region nearby the source.

4. The method of claim 3 wherein the first programming state represents that both the first region and the second region are not injected with electrons, the second programming state represents that the second region is not injected with electrons but the first region, the third programming state represents that the first region is not injected with electrons but the second region, and the fourth programming state represents that both the first region and the second region are injected with electrons.

5. The method of claim 3, wherein the non-conducting dielectric layer comprises silicon nitride.

6. The method of claim 3, wherein the first isolation layer and the second isolation layer both comprise silicon dioxide.

7. The method of claim 3, wherein the conductor comprises polysilicon.
